(19) United States
(12) Patent Application Publication
(10) Pub. No.: US 2023/0207757 A1
(43) Pub. Date: Jun. 29, 2023

(54) LED LIGHT SOURCE AND PACKAGING METHOD THEREOF

(71) Applicant: YONGBING ZHANG, Shantou (CN)

(72) Inventor: YONGBING ZHANG, Shantou (CN)

(21) Appl. No.: 17/562,628

(22) Filed: Dec. 27, 2021

(51) Int. Cl. H01L 33/62; H01L 27/15; H01L 33/00

(52) U.S. Cl. CPC H01L 33/62; H01L 27/153; H01L 33/005; H01L 2933/0033

(57) ABSTRACT

The present disclosure provides an LED light source. The LED light source includes a first substrate, a second substrate located at a side of the first substrate, and a gap located between the first substrate and the second substrate, at least one LED chip facing the gap and connected between the first substrate and the second substrate, and a packaging adhesive covering the at least one LED chip and located at the gap.

### FIELD OF THE INVENTION

The present disclosure relates to light sources technology field, and specifically to an LED (Light Emitting Diode) light source and a packaging method thereof.

### BACKGROUND OF THE INVENTION

An LED (Light Emitting Diode) is a solid-state semiconductor device, which can directly convert electric energy into light energy. The heart of the LED is a semiconductor chip. One end of the chip is attached to a bracket, which is a negative electrode, and the other end is connected to a positive electrode of a power supply. The whole chip is encapsulated by epoxy resin. The chip consists of two parts, one part is a p-type semiconductor, in which holes dominate, and the other part is an n-type semiconductor, mainly electrons. When the two semiconductors are connected, a “p-n junction” is formed between them. During current acts on the chip through wires, the electrons will be pushed to a p region of the p-n junction, where the electrons compound with holes, and then emit energy in the form of photons. This is the principle of LED light sources.

LED chips need to be protected from dust and moisture. For electrostatic discharge (ESD) and mechanical damage, reliable ohmic contact needs to be established to apply current to the p-n junction. When applying current, heat generated in the p-n junction needs to be released to prevent the LED chip from overheating. Therefore, the industry is committed to conducting the heat generated by the LED chip through continuous progress and new materials.

### SUMMARY OF THE INVENTION

The present disclosure provides an LED light source including a first substrate; a second substrate located at a side of the first substrate, and a gap located between the first substrate and the second substrate; at least one LED chip facing the gap and connected between the first substrate and the second substrate, and a packaging adhesive covering the at least one LED chip and located at the gap.

Further, the first substrate includes a first surface, a second surface opposite to the first surface, a first side surface adjacent to the second substrate and connected between the first surface and the second surface, the second substrate includes a third surface, a fourth surface opposite to the third surface, a second side surface facing with the first side surface and connected between the third surface and the fourth surface, the at least one LED chip includes a first electrode connected with the first surface and a second electrode connected with the third surface, the gap is located between the first side surface and the second side surface, the packaging adhesive includes a first part covering the at least one LED chip, the first surface and the third surface and a second part located at the gap.

Further, the packaging adhesive further includes a third part covering at least a part of the second surface, a fourth part covering at least a part of the fourth surface, and a fifth part connected with the second part, the third part and the fourth part.

Further, the second surface includes a first groove adjacent to the second substrate, the fourth surface includes a second groove adjacent to the first substrate, the third part is located at the first groove, and the fourth part is located at the second groove.

Further, the first electrode is connected to the first surface with a first conductive material, and the second electrode is connected to the third surface with a second conductive material, the first conductive material is a conductive film, conductive gel or welding material, and the second conductive material is a conductive film, conductive gel or welding material.

Further, the LED light source further includes a first mounted pad disposed on the first substrate and a second mounted pad disposed on the second substrate.

Further, the first mounted pad is located a third side surface of the first substrate far away from the second substrate, and the second mounted pad is located a fourth side surface of the second substrate far away from the first substrate.

Further, the first substrate is a PCB or a metal board, and the second substrate is a PCB or a metal board.

Further, the packaging adhesive includes epoxy resin or silica gel.

The present disclosure also provides a packaging method of an LED light source including: providing a first substrate, a second substrate and at least one LED chip; disposing the second substrate at a side of the first substrate with a gap is located between the first substrate and the second substrate; bonding the at least one LED chip on the first substrate and the second substrate and facing the gap, and providing a packaging adhesive covering the at least one LED chip and filling the gap.

Further, the first substrate includes a first surface, a second surface opposite to the first surface, a first side surface adjacent to the second substrate and connected between the first surface and the second surface, the second substrate includes a third surface, a fourth surface opposite to the third surface, a second side surface facing with the first side surface and connected between the third surface and the fourth surface, the at least one LED chip includes a first electrode connected with the first surface and a second electrode connected with the third surface, the gap is located between the first side surface and the second side surface, the packaging adhesive includes a first part covering the at least one LED chip, the first surface and the third surface and a second part located at the gap.

Further, the packaging adhesive further includes a third part covering at least a part of the second surface, a fourth part covering at least a part of the fourth surface, and a fifth part connected with the second part, the third part and the fourth part.

Further, the second surface includes a first groove adjacent to the second substrate, the fourth surface includes a second groove adjacent to the first substrate, the third part is located at the first groove, and the fourth part is located at the second groove.

Further, the first electrode is connected to the first surface with a first conductive material, and the second electrode is connected to the third surface with a second conductive material, the first conductive material is a conductive film, conductive gel or welding material, and the second conductive material is a conductive film, conductive gel or welding material.

Further, the LED light source further includes a first mounted pad disposed on the first substrate and a second mounted pad disposed on the second substrate.

Further, the first mounted pad is located a third side surface of the first substrate far away from the second substrate, and the second mounted pad is located a fourth side surface of the second substrate far away from the first substrate.

Further, the first substrate is a PCB or a metal board, and the substrate is a PCB or a metal board.

Further, the packaging adhesive includes epoxy resin or silica gel.

The present disclosure further provides an LED light source including a first substrate; a second substrate located at a side of the first substrate and independent with the second substrate, and a gap is located between the first substrate and the second substrate; at least one LED chip facing the gap and connected between the first substrate and the second substrate, and a packaging adhesive covering the at least one LED chip and filling the gap.

Further, the first substrate includes a first groove located a second surface far away from the LED chip and adjacent to the second substrate, the second substrate includes a second groove located a fourth surface far away from the LED chip and adjacent to the first substrate, the packaging adhesive covers the LED chip, a first surface of the first substrate adjacent to the LED chip, a third surface of the second substrate adjacent to the LED chip and fills the gap, the first groove and the second groove.

Due to the gap, the LED chip can emit light to a bottom side of the LED light source, this is the LED light source may have six emitting surfaces, and an luminous angle may be 360 degree. Furthermore, the LED light source has novel structure, no welding wires and easy to manufacture.

### BRIEF DESCRIPTIONS OF THE DRAWINGS

For the purpose of a clearer description of the embodiments in this application or technical solutions in prior art, below is a brief introduction of the attached drawings needed to be used in the description of the embodiments or prior art. Apparently, the attached drawings in the following description are only some embodiments indicated in the present application. For ordinary skill in the art, they may obtain other drawings according to these attached drawings without any innovative laboring.

The present disclosure will be further described with reference to the attached drawings and the embodiments hereunder.

FIG. 1 is a cross-section view of an LED light source without packaging adhesive in a related packaging technology of the present disclosure;

FIG. 2 is a cross-section view of the LED light source of FIG. 1 with the packaging adhesive;

FIG. 3 is a cross-section view of a PCB of the LED light source of FIG. 1;

FIG. 4 is a schematic view of an LED light source according to one embodiment of the present disclosure;

FIG. 5 is a cross-section view of the LED light source of FIG. 4 without packaging adhesive;

FIG. 6 is a cross-section view of the LED light source of FIG. 4;

FIG. 7 is a top view of the LED light source of FIG. 5;

FIG. 8 is a top view of the LED light source of FIG. 4;

FIG. 9 is a bottom view of the LED light source of FIG. 4; and

FIG. 10 is a flow chart of a packaging method of the LED light source of FIG. 4 according to one embodiment of the present disclosure.

### DETAILED DESCRIPTION OF THE ILLUSTRATED EMBODIMENTS

In order to provide a clear understanding of the objects, features, and advantages of the embodiments, the following are detailed and complete descriptions to the technological solutions adopted in the embodiments. Obviously, the descriptions are part of the whole embodiments. The other embodiments which are not processed creatively by technicians of ordinary skills in the field are under the protection of this disclosure. The same is given with reference to the drawings and specific embodiments. It should be noted that non-conflicting embodiments in the disclosure and the features in the embodiments may be combined with each other without conflict.

In the following description, numerous specific details are set forth in order to provide a full understanding of the disclosure. The disclosure may be practiced otherwise than as described herein. The following specific embodiments are not to limit the scope of the disclosure.

Unless defined otherwise, all technical and scientific terms herein have the same meaning as used in the field of the art as generally understood. The terms used in the disclosure are to describe particular embodiments and are not intended to limit the disclosure.

The disclosure, referencing the accompanying drawings, is illustrated by way of examples and not by way of limitation. It should be noted that references to “an” or “one” embodiment in this disclosure are not necessarily to the same embodiment, and such references mean “at least one.”

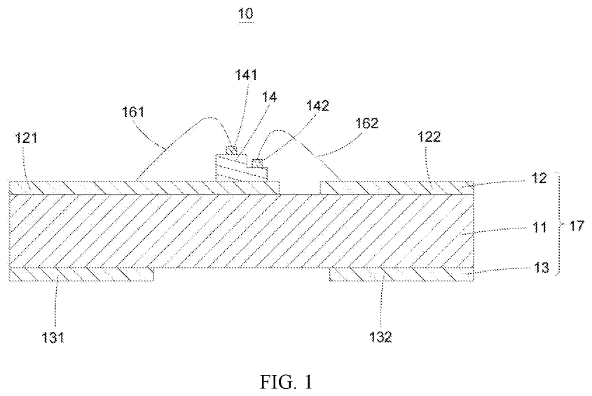

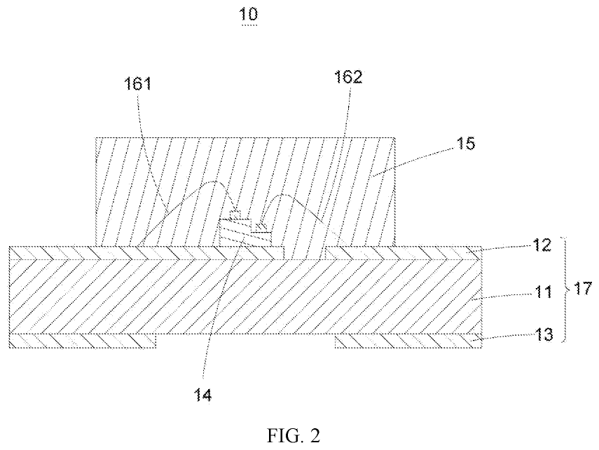

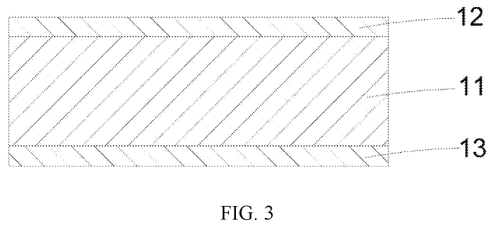

In a related packaging technology, epoxy resin or silica gel is molded on a PCB board by a molding method to protect the LED chip. Referring to FIGS. 1-3, an LED light source 10 includes a PCB (Printed Circuit Board) 17, a LED chip 14, and a packaging adhesive 15. The PCB 17 includes an insulating layer 11, a first conductive layer 12 disposed on a first surface of the insulating layer 11, a second conductive layer 13 disposed on a second surface opposite to the first surface. The LED chip 14 is disposed on the first conductive layer 12, and a packaging adhesive 15 covers the LED chip 14. The LED chip 14 includes a first electrode 141 and second electrode 142, the first electrode 141 is connected to a first part 121 of the first conductive layer 12 via a first welding wire 161, and the second electrode 142 is connected to a second part 122 of the first conductive layer 12 via a second welding wire 162. The packaging adhesive 15 may include epoxy resin or silica gel and be disposed on the LED chip 14, the first part 121 and the second part 122. The second conductive layer 13 may include a first bonding pad 131 and a second bonding pad 132 for electrically connecting external devices.

The above LED light source 10 is to mold a packaging adhesive 15 on a surface of planar PCB to cover the LED chip 14. It may only emit light on five surfaces, and a luminous angle may be only 180 degrees. In order to overcome the disadvantage of the existing LED light source 10, the present disclosure provides an LED light source 20 and a packaging method thereof, which has the advantages of novel structure, no welding wires and easy to manufacture.

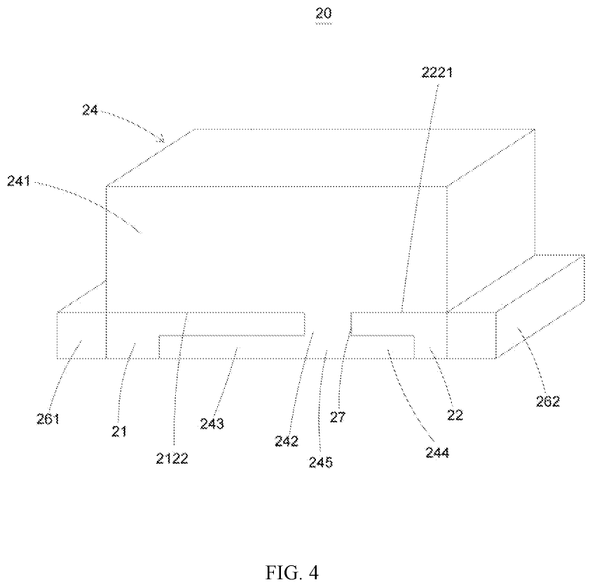

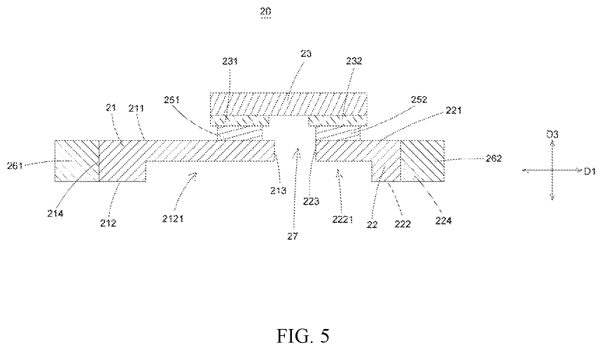

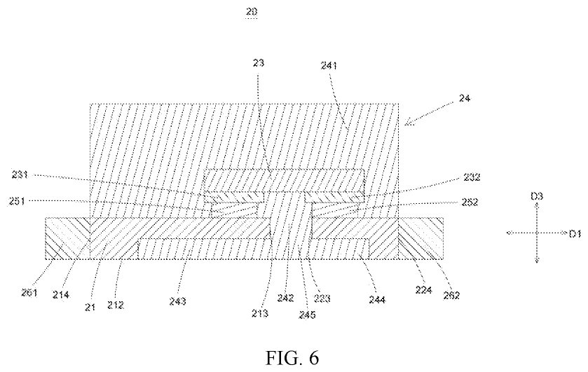

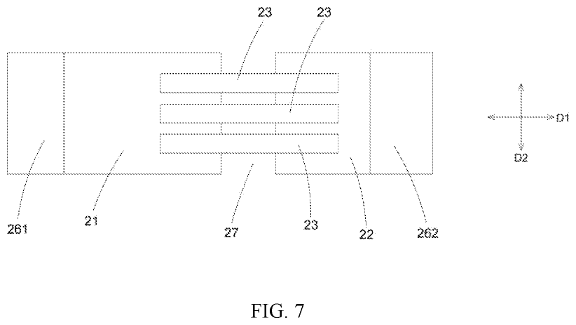

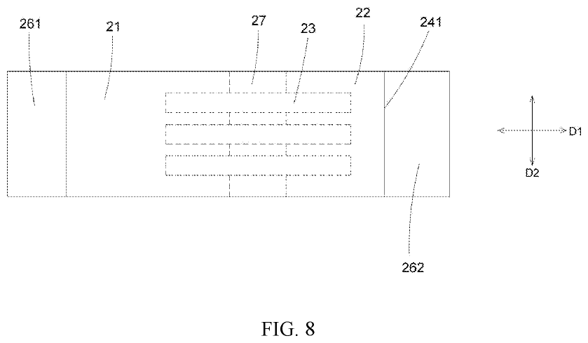

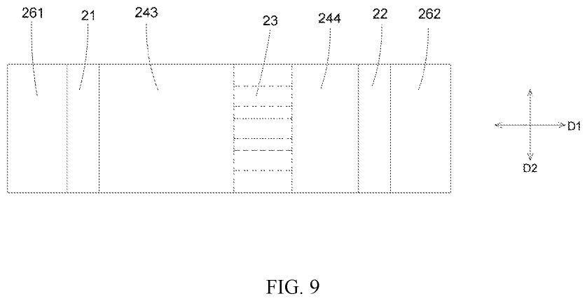

Referring to FIGS. 4-9, the LED light source 20 according to one embodiment of the present disclosure includes a first substrate 21, a second substrate 22 located at a side of the first substrate 21, at least one LED chip 23, a packaging adhesive 24, a first conductive material 251, a second conductive material 252, a first mounted pad 261 and a second first mounted pad 262.

The first substrate 21 may be a PCB or a metal board, and the second substrate 22 is also a PCB or a metal board. In the embodiment, the second substrate 22 is independent with the first substrate 21, the second substrate 22 is located at a side of the first substrate 21 along a first direction D1, and a gap 27 is located between the first substrate 21 and the second substrate 22. The at least one LED chip 23 may be located at a top side of the first substrate 21 and the second substrate 22, and the at least one LED chip 23 face the gap 27 and connect between the first substrate 21 and the second substrate 22. The packaging adhesive 24 covers the at least one LED chip 23 and is located at the gap 27. In can be understood, the packaging adhesive 24 is made of insulation and light guide material, such that light from the LED chip 23 may pass through the packaging adhesive 24. In the embodiment, the packaging adhesive 24 can be made of epoxy resin or silica gel.

The at least one LED chip 23 may include one LED chip, two or more LED chips, in the embodiment, the at least one LED chip 23 includes three LED chips 23 arranged along a second direction D2 perpendicular to the first direction D1.

The first substrate 21 includes a first surface 211, a second surface 212 opposite to the first surface 211, a first side surface 213 adjacent to the second substrate 22 and connected between the first surface 211 and the second surface 212. The second substrate 22 includes a third surface 221, a fourth surface 222 opposite to the third surface 221, a second side surface 223 facing with the first side surface 213 and connected between the third surface 221 and the fourth surface 222. The LED chip 23 includes a first electrode 231 connected with the first surface 211 and a second electrode 232 connected with the third surface 221, the gap 27 is located between the first side surface 213 and the second side surface 223.

The first electrode 231 is connected to the first surface 211 with the first conductive material 251, and the second electrode 232 is connected to the third surface 221 with a second conductive material 252. In the embodiment, the first conductive material 251 can be a conductive film, conductive gel or welding material, and the second conductive material 152 is a conductive film, a conductive gel or welding material, such that there is no welding wires in the LED light source 20.

The packaging adhesive 24 includes a first part 241 covering the LED chip 23, the first surface 211 and the third surface 221, a second part 242 fill the gap 27, a third part 243 covering at least a part of the second surface 212, a fourth part 244 covering at least a part of the fourth surface 222, and a fifth part 245 connected with the second part 242, the third part 243 and the fourth part 244. In addition, the packaging adhesive 24, the first substrate 21, and the second substrate 21 may form a cuboid structure having six surfaces, a length L of the cuboid structure along the first direction D1 is less than or equal to 5 mm, a width W of the cuboid structure along the second direction D2 is less than or equal to 4 mm, and a height H of the cuboid structure along the third direction D3 perpendicular to the first direction D1 and the second direction is less than or equal to 3 mm.

Furthermore, in the embodiment, the second surface 212 includes a first groove 2121 adjacent to the second substrate 22, the fourth surface 222 includes a second groove 2221 adjacent to the first substrate 21, the third part 243 is located at the first groove 2121, and the fourth part 244 is located at the second groove 2221.

The first mounted pad 261 is disposed on the first substrate 21 and the second mounted pad 262 is disposed on the second substrate 22. The first mounted pad 261 and the second mounted pad 262 are configured to electrically connecting external devices. In the embodiment, the first mounted pad 261 is located a third side surface 214 of the first substrate 21 far away from the second substrate 22, and the second mounted pad 262 is located a fourth side surface 224 of the second substrate 22 far away from the first substrate 21.

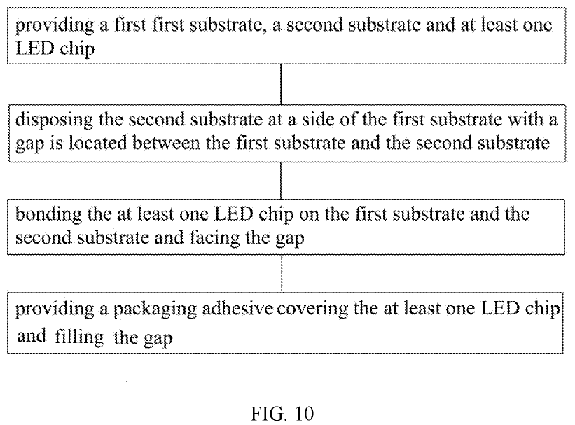

Referring to FIGS. 4-10, a packaging method of the LED light source 20 includes providing a first substrate, a second substrate and at least one LED chip; disposing the second substrate at a side of the first substrate with a gap located between the first substrate and the second substrate; bonding the at least one LED chip on the first substrate and the second substrate and facing the gap, and providing a packaging adhesive covering the at least one LED chip and filling the gap.

In step S1, the first substrate 21, the second substrate 22 and at least one LED chip 23 are provided.

In step S2, the second substrate 22 is disposed at a side of the first substrate 21, and the gap 27 is located between the first substrate and the second substrate.

In step S3, at least one LED chip 23 is provided to face the gap and bonded on the first substrate 21 and the second substrate 22 and faces the gap 27. In the embodiment, the first electrode 231 is bonding on the first surface 211 of the first substrate 21, and the second electrode is bonding on the third surface 221 of the second substrate 22.

In step S4, the packaging adhesive 24 is provided to cover the at least one LED chip 23 and fill the gap 27. In the embodiment, the packaging adhesive 24 covers the at least one LED chip 23, the first surface 211, the third surface 221, the first side surface 213, the second side surface 223, at least a part of the second surface 212 and at least a part pf the fourth surface 222, and fills the gap 27, the first groove 2121 and the second groove 2221.

Due to the gap 27, the LED chip 23 can emit light to a bottom side of the LED light source 20, this is the LED light source 20 may have six emitting surfaces, and an luminous angle may be 360 degree. Furthermore, the LED light source 20 has novel structure, no welding wires and easy to manufacture.

Finally, it should be noted that above embodiments are merely used for illustrating the technical solutions of the disclosure, rather than limiting the disclosure; though the disclosure is illustrated in detail with reference to the aforementioned embodiments, it should be understood by those of ordinary skill in the art that modifications may still be made on the technical solutions disclosed in the aforementioned respective embodiments, or equivalent substitutions may be made to a part of technical features thereof; and these modifications or substitutions do not make the essence of the corresponding technical solutions depart from the spirit and scope of the technical solutions of the respective embodiments of the disclosure.

What is claimed is:

1. An LED light source, comprising:
a first substrate;
a second substrate located at a side of the first substrate, and a gap located between the first substrate and the second substrate;
at least one LED chip facing the gap and connected between the first substrate and the second substrate; and
a packaging adhesive covering the at least one LED chip and located at the gap.

2. The LED light source of claim 1, wherein the first substrate comprises a first surface, a second surface opposite to the first surface, a first side surface adjacent to the second substrate and connected between the first surface and the second surface, the second substrate comprises a third surface, a fourth surface opposite to the third surface, a second side surface facing with the first side surface and connected between the third surface and the fourth surface, the at least one LED chip comprises a first electrode connected with the first surface and a second electrode connected with the third surface, the gap is located between the first side surface and the second side surface, the packaging adhesive comprises a first part covering the at least one LED chip, the first surface and the third surface and a second part located at the gap.

3. The LED light source of claim 2, wherein the packaging adhesive further comprises a third part covering at least a part of the second surface, a fourth part covering at least a part of the fourth surface, and a fifth part connected with the second part, the third part and the fourth part.

4. The LED light source of claim 3, wherein the second surface comprises a first groove adjacent to the second substrate, the fourth surface comprises a second groove adjacent to the first substrate, the third part is located at the first groove, and the fourth part is located at the second groove.

5. The LED light source of claim 2, wherein the first electrode is connected to the first surface with a first conductive material, and the second electrode is connected to the third surface with a second conductive material, the first conductive material is a conductive film, conductive gel or welding material, and the second conductive material is a conductive film, conductive gel or welding material.

6. The LED light source of claim 1, wherein the LED light source further comprises a first mounted pad disposed on the first substrate and a second mounted pad disposed on the second substrate.

7. The LED light source of claim 6, wherein the first mounted pad is located a third side surface of the first substrate far away from the second substrate, and the second mounted pad is located a fourth side surface of the second substrate far away from the first substrate.

8. The LED light source of claim 1, wherein the first substrate is a PCB or a metal board, and the second substrate is a PCB or a metal board.

9. The LED light source of claim 1, wherein the packaging adhesive comprises epoxy resin or silica gel.

10. A packaging method of an LED light source, comprising the steps of:
providing a first substrate, a second substrate and at least one LED chip;
disposing the second substrate at a side of the first substrate with a gap located between the first substrate and the second substrate;
bonding the at least one LED chip on the first substrate and the second substrate and facing the gap; and
providing a packaging adhesive covering the at least one LED chip and filling the gap.

11. The method of claim 10, wherein the first substrate comprises a first surface, a second surface opposite to the first surface, a first side surface adjacent to the second substrate and connected between the first surface and the second surface, the second substrate comprises a third surface, a fourth surface opposite to the third surface, a second side surface facing with the first side surface and connected between the third surface and the fourth surface, the at least one LED chip comprises a first electrode connected with the first surface and a second electrode connected with the third surface, the gap is located between the first side surface and the second side surface, the packaging adhesive comprises a first part covering the at least one LED chip, the first surface and the third surface and a second part located at the gap.

12. The method of claim 11, wherein the packaging adhesive further comprises a third part covering at least a part of the second surface, a fourth part covering at least a part of the fourth surface, and a fifth part connected with the second part, the third part and the fourth part.

13. The method of claim 12, wherein the second surface comprises a first groove adjacent to the second substrate, the fourth surface comprises a second groove adjacent to the first substrate, the third part is located at the first groove, and the fourth part is located at the second groove.

14. The method of claim 11, wherein the first electrode is connected to the first surface with a first conductive material, and the second electrode is connected to the third surface with a second conductive material, the first conductive material is a conductive film, conductive gel or welding material, and the second conductive material is a conductive film, conductive gel or welding material.

15. The method of claim 10, wherein the LED light source further comprises a first mounted pad disposed on the first substrate and a second mounted pad disposed on the second substrate.

16. The method of claim 15, wherein the first mounted pad is located a third side surface of the first substrate far away from the second substrate, and the second mounted pad is located a fourth side surface of the second substrate far away from the first substrate.

17. The method of claim 10, wherein the first substrate is a PCB or a metal board, and the substrate is a PCB or a metal board.

18. The method of claim 10, wherein the packaging adhesive comprises epoxy resin or silica gel.

19. An LED light source, comprising:
a first substrate;
a second substrate located at a side of the first substrate and independent with the second substrate, and a gap is located between the first substrate and the second substrate;
at least one LED chip facing the gap and connected between the first substrate and the second substrate; and
a packaging adhesive covering the at least one LED chip and filling the gap.

20. The light source of claim 19, wherein the first substrate comprises a first groove located a second surface far away from the LED chip and adjacent to the second substrate, the second substrate comprises a second groove located a fourth surface far away from the LED chip and adjacent to the first substrate, the packaging adhesive covers the LED chip, a first surface of the first substrate adjacent to the LED chip, a third surface of the second substrate adjacent to the LED chip and fills the gap, the first groove and the second groove.
